(19) United States
(12) Patent Application Publication
(10) Pub. No.: US 2021/0289644 A1
(43) Pub. Date: Sep. 16, 2021

(54) DISPLAY SUPPORTS

(71) Applicant: HEWLETT-PACKARD DEVELOPMENT COMPANY, L.P., Spring, TX (US)

(72) Inventors: Arthur Zarnowitz, Palo Alto, CA (US); Cian Plumbe, London (GB); Harc Lee, London (GB); Andrew Guscott, London (GB); Ifung Lu, London (GB); Gianluca Berutti, London (GB); Isaac Teece, London (GB); Marcus Hoggarth, London (GB); Victor Su, Taipei (TW)

(21) Appl. No.: 16/482,283

(22) PCT Filed: Jul. 24, 2017
(86) PCT No.: PCT/US2017/043544

§ 371 Date: Jul. 31, 2019

(51) Int. Cl. H05K 5/02; F16M 11/20

(52) U.S. Cl. CPC H05K 5/0234; F16M 2200/063; F16M 11/2021

(57) ABSTRACT

Some examples include a support for a display device including a first arm having a first end, an opposing second end, and a body having a width and a length, the first end pivotably coupled to a display device, the second end pivotably coupled to a base, a first cam and a second cam coupled to the first arm, and a second arm extending along the body of the first arm, the second arm having a proximal end movably coupled to the first arm at the first cam and a distal end movably coupled to the first arm at the second cam, the second arm extending within the width and the length of the first arm in a retracted state, and the second arm extending outside of the width and within the length of the first arm in an extended state.

### BACKGROUND

Many display devices include support to position the display device on a work surface. Some display devices include adjustable support of the display device.

### BRIEF DESCRIPTION OF THE DRAWINGS

FIGS. 1A-1C are side views of an example support coupled to a display device and a base in accordance with aspects of the present disclosure.

FIG. 2A-2B are expanded cross-sectional views of an example of a support for a display device in accordance with aspects of the present disclosure.

FIGS. 3A and 3B are expanded cross-sectional illustrations of another example of a support for a display device in accordance with aspects of the present disclosure.

FIG. 4 is a back view of an example display support system in accordance with aspects of the present disclosure.

FIG. 5 is a flow chart of an example method of repositioning a support coupled to a display device in accordance with aspects of the present disclosure.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

A support for a display device typically includes, or extends from, a base placed on a horizontal surface and adjustment units for adjustably connecting the base to the display device. The support for the display device can have a variety of adjusting units for rotating, tilting, swiveling, raising, and lowering the display device. For example, adjustment units such as hinges are often included for adjusting the height and tilt of the display device. Multiple degrees of adjustments often include multiple separate adjustment units, increasing the complexity and the overall size/volume of the support. Minimizing the size of the support can be desirable. In accordance with aspects of the present disclosure, support including a four-bar linkage mechanism can have a reduced cross-sectional profile with linkage arms that are externally exposed and without being encased in a housing. Four-bar linkage mechanisms are formed of a movable closed chain linkage connected in a loop by four joints.

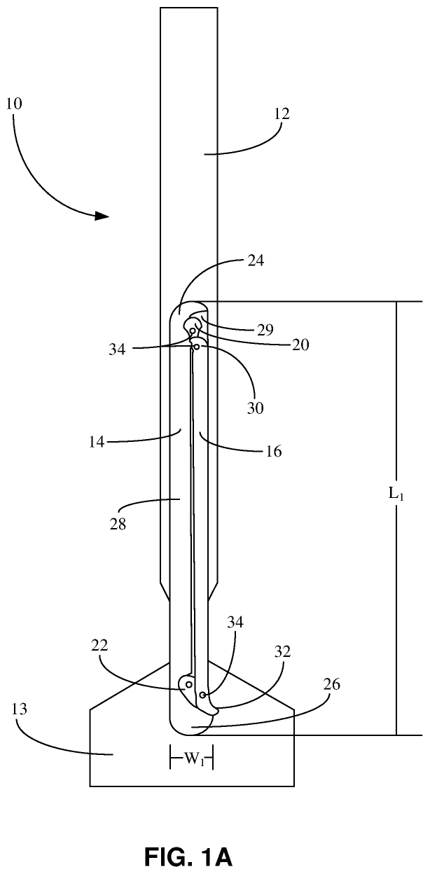

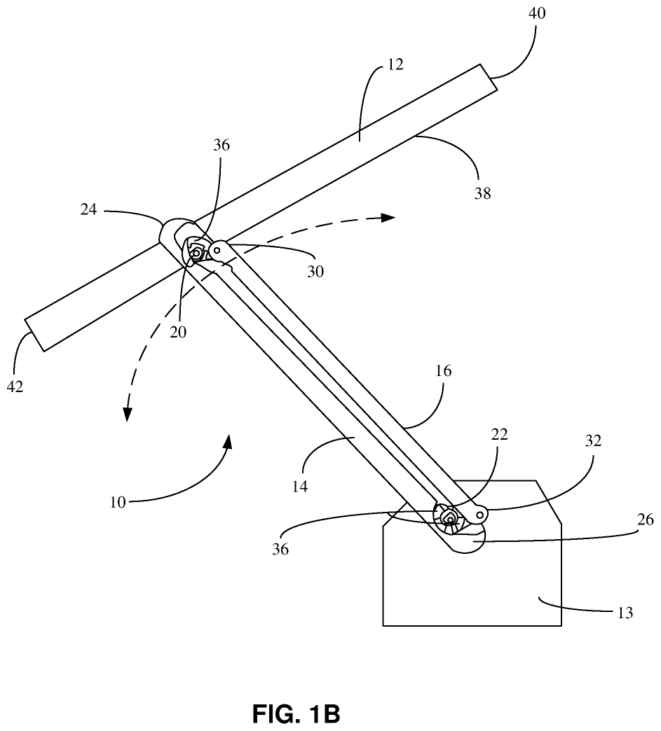

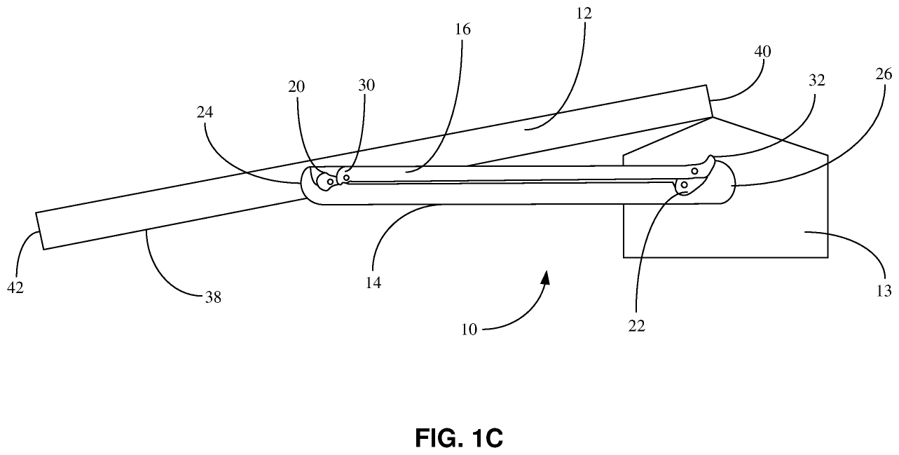

FIG. 1A illustrates a support 10 for a display device 12 in accordance with aspects of the present disclosure. In general terms, support 10 connects display device 12 to a base 13 for movable support of display device 12. Support 10 can provide tilt and height adjustment for display device 12, for example. Support 10 includes a first arm 14, a second arm 16, a first cam 20, and a second cam 22. First arm 14 has a first end 24, a second end 26, and a body 28 extending between first and second ends 24, 26. In one example, first end 24 is coupled, or fixed, to display device 12 and second end 26 is coupled, or fixed, to base 13.

Second arm 16 extends along body 28 of first arm 14. Second arm 16 is a “floating” arm that is movable relative to first arm 14 by first and second cams 20, 22. Body 28 of first arm 14 has a length “L₁” and a width “W₁”. Length L₁ extends between first and second ends 24, 26 and width W₁ extends perpendicular to length L₁. Length L₁ can be greater than width W₁. Second arm 16 can be sized to fit within the length L₁ and width W₁ of first arm 14. In other words, second arm 16 can have a length that is less than length L₁ of first arm 14 and a width that is less than width W₁ of first arm 14. In one example, first and second arms 14, 16 are formed as flat bars. In one example, second arm 16 is a flat bar and first arm 14 is U-shaped. In one example, first and second arms 14, 16 are each generally linear. In one example, first arm 14 includes a recess 29, partially visible in FIG. 1A, that is sized and shaped to accommodate second arm 16 and first and second cams 20, 22. First and second arms 14, 16 can be formed of any suitable material having the desired appearance and functional properties. For example, first and second arms 14, 16 can be formed of steel, aluminum, carbon fiber, or other suitable material. First and second arms 14, 16 can be formed by one or more of the processes of forging metal, computer numerical control (CNC) machining, stamping, or die-casting, for example. First and second cams 20, 22 can be formed by metal injection molding or other suitable process.

Second arm 16 is movably coupled to first arm 14 at first and second cams 20, 22. Second arm 16 has a proximal end 30 and a distal end 32. Proximal end 30 and distal end 32 are independently coupled, or linked, to first arm 14 adjacent or along first and second ends 24, 26 with first and second cams 20, 22, respectively. First and second cams 20, 22 can be coupled to first and second arms 14, 16 with pins 34 or other suitable fasteners that allow pivotal or rotational movement of first and second cams 20, 22 relative to first and second arms 14, 16. For example, proximal end 30 can be coupled to first arm 14 at first cam 20 with pins 34 and distal end 32 can be coupled to first arm 14 at second cam 22 with pins 34. More particularly, pin 34 pivotably couples proximal end 30 to first cam 20 and another pin 34 pivotably couples first cam 20 to first arm 14. Similarly, pin 34 pivotably couples distal end 32 to second cam 22 and another pin 34 pivotably couples second cam 22 to first arm 14.

In some examples, first and second cams 20, 22 are sized and positioned to extend within recess 29 formed in first arm 14. In some examples, first cam 20 and second cam 22 each include a stop 36 (see, e.g. FIG. 1B). In some examples, stop 36 on first cam 20 can be sized and positioned different that of stop 36 on second cam 22. More than one stop 36 can be included on first and second cam 20, 22. Stops 36 can limit movement of second arm 16 relative to first arm 14.

First and second cams 20, 22 coupled to first and second arms 14, 16 can provide for synchronized display device 12 tilt with support 10 angle change. For example, as display device 12 is repositioned (e.g., raised or lowered and tilted), first arm 14 pivots with respect to display device 12 and base 13 and first and second cams 20, 22 rotate to move second arm 16 relative to first arm 14. An overall width of support 10 can change while an overall length of support 10 remains the same (i.e., equivalent to length L₁ of first arm 14) as second arm 16 is moved within and outside of width W₁ of first arm 14. In one example, the first and second arms 14, 16 change from closest together, or contracted, in the down position (see, e.g., FIG. 1C) to farthest apart, or enlarged, in the raised upright position (see, e.g., FIG. 1B).

In one example, first end 24 is pivotably coupled to display device 12 and second end 26 is pivotably coupled to base 13. Display device 12 can be rotatable about an axis defined at first end 24 coupling with display device 12. Support 10 can also provide for movement of display device 12 along an arc and having an arc length formed between base and display device 12 by support 10, as indicated by a dashed curved line in FIG. 1B. Arc length can be limited by first and second cam 20, 22. First and second cams 20, 22 coupled with first and second arms 14, 16 can provide control of weight torque through a range of motion of display device 12.

Display device 12 can be any type of desired display device. For example, display device 12 can be an electronic display device such as a monitor or television. Display device 12 can be an integrated computing device. In one example, display device 12 can have a touch type screen. Support 10 can be sized and formed of suitable material to accommodate a size and weight of display device 12. Support 10 coupled to base 13 can provide control of weight torque through display device 12 range of motion. Base 13 can provide balance and counterweight to support 10 during repositioning and in the various positions display device 12 is movable into. Base 13 can be mounted to a surface, such as tabletop (not shown), for example. Base 13 can be any appropriate size, shape, and weight to support display device 12 in a variety of positions.

As illustrated in FIG. 1A, first and second arms 14, 16 of support 10 extend parallel to one another in a vertical display position of display device 12, or first position. In the first position of display device 12, first and second arms 14, 16 are in a retracted state with second arm 16 extending within length L₁ and width W₁ of first arm 14. FIG. 1C illustrates display device 12 in an inking position. In one example, display device 12 is angled 10-30 degrees from horizontal in inking position. In one example, display device 12 is approximately 20 degrees from horizontal in inking position. In one example, a back surface of display device can be positioned against a top of base in inking position. In one example, support 10 can be generally vertical in vertical display position of display device 12 and generally horizontal in inking position of display device 12. In one example, first arm and second arm 14, 16 are in a retracted state, or un-extended state, in both an upright display position and inking position as illustrated in FIGS. 1A and 1C. Alternatively, first and second arm 14, 16 can be in an expanded state with second arm 16 extending outside of the width W₁ of first arm 14 and within the length L₁ of first arm 14 while in one or both of vertical display position and inking position. FIG. 1B illustrates display device 12 in a transitioning position, between display position and inking position. In one example, as a user moves display device 12 between display position and inking position, first and second cams 20, 22 are rotated to move second arm 16 extended outside of the width W₁ of first arm 14. User can reposition display device 12 by pushing and/or pulling against a top 40 or a bottom 42 of display device 12. First and second cams 20, 22 are movable in response to pivotal movement of the first arm 14, with second arm 16 moving relative to first arm 14 in response to first and second cam 20, 22 movement.

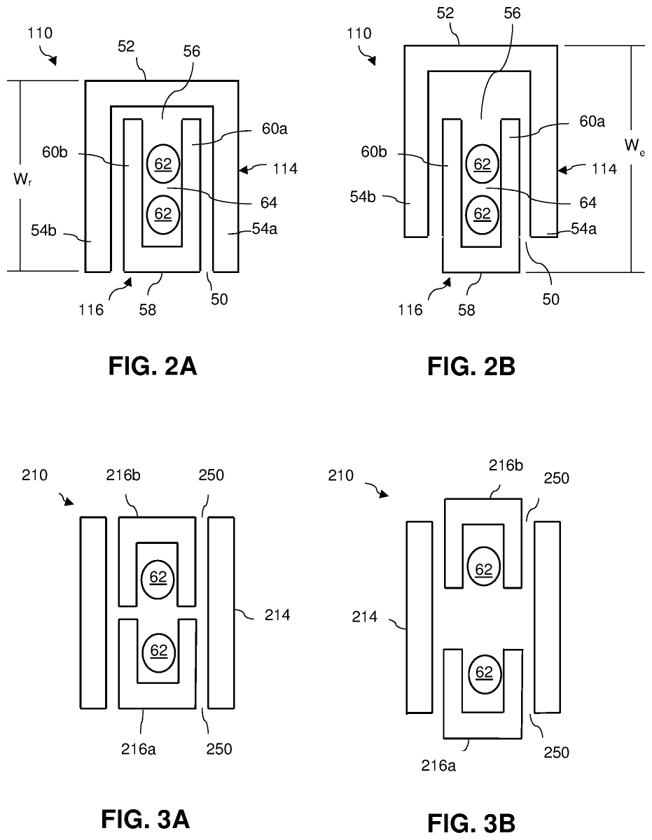

FIGS. 2A and 2B illustrate enlarged cross-sectional views of another example support 110 for display device 12 in accordance with aspects of the present disclosure. In one example, first and second arm 114, 116 are each formed as a U-shaped channel along respective lengths. In another example, second arm 116 is a flat bar. First arm 114 and second arm 116 can be interlocked to minimize a cross-section size of support 110 with first arm 114 forming an exterior of support 110. For example, first arm 114 can include a first open side 50, a first closed side 52 opposite first open side 50, and first opposing legs 54a, 54b extending from first closed side 52 toward first open side 50. Second arm 116 can be similarly formed, with a second open side 56, a second closed side 58 opposite second open side 56, and opposing legs 60a, 60b extending from second closed side 58 toward second open side 56. In one example, second arm 116 is sized to slidably fit within and between first opposing legs 54a, 54b and within first arm 114. In one example, second closed side 58 extends across first open side 50 between terminal ends of first opposing legs 54a, 54b. In one example, second arm 116 is movably disposed within first arm 114. In one example, first open side 50 of first arm 114 is oppositely disposed from second open side 56 of second arm 116. In one example, second arm 116 is sized to accommodate electronic cables 62 of display device 12. In another example, where second arm 116 is a flat bar, electronic cables 62 are fit within first arm 114 with second arm 116.

Similar to support 10, first and second arms 114, 116 of support 110 are movable between retracted and expanded states. FIG. 2A illustrates support 110 in the retracted state and having an overall width Wᵣ defined by a width of first arm 114. FIG. 2B illustrates support 110 in the expanded state and having an overall expanded width Wₑ defined by the width of first arm 114 and an extended portion of second arm 116. First and second arms 114, 116 can be disposed together to define a cavity 64. Cavity 64 is suitable to house cable 62 extending through. In one example, cavity 64 can house more than one cable 62. Cavity 64 can assist with cable management of cables 62 connecting to and extending from display device 12 such as electronic and networking cables, for example. The volume of cavity 64 changes as first and second arms 114, 116 are extended away from each other (see, e.g., FIG. 2B) and positioned together in a retracted state (see, e.g., FIG. 2A). Second arm 114 can be formed with an interior sized to accommodate housing cable 62 within.

FIGS. 3A and 3B are cross-sectional illustrations of another example of a support 210 for display device 10 in accordance with aspects of the present disclosure. FIG. 3A illustrates support 210 in a retracted state and FIG. 3B illustrates support 210 in an expanded state. In this example, an additional second, or floating, arm 216b can be included with a second arm 216a and coupled to a first arm 214 to provide additional strength to support and relieve stress placed on first arm 214 by display device 10. For example, second arms 216a, 216b can be movably attached to first arm 214 to extend from opposite open sides 250 of first arm 214. Although not shown, each second arm 216a, 216b is pivotably coupled to first arm 214 with first and second cams and each second arm 216a can be formed as a planar flat bar instead of U-shaped.

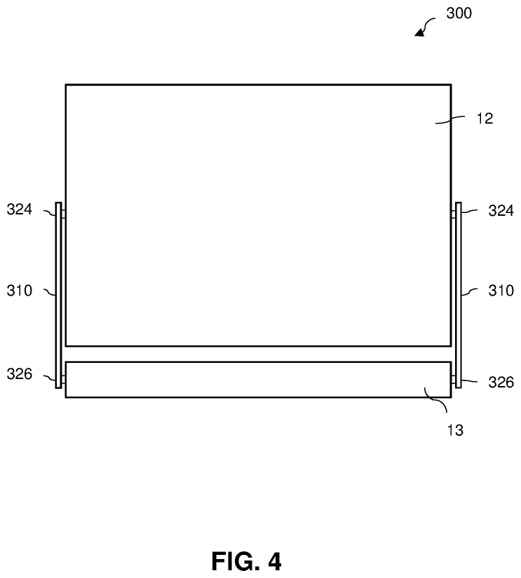

FIG. 4 illustrates a back view of a display system 300 including a support 310. Support 310 includes features similar to supports 10, 110, 210. In one example, a pair of supports 310 are included with one of the pair of supports 310 disposed along opposing sides of display device 12. In one example, first end 324 is coupled, or fixed, to display device 12 and second end 326 is coupled, or fixed, to base 13.Supports 310 can each be pivotably coupled to display device 12 and base 13 to move display device 12 between positions illustrated in FIGS. 1A-1C. Supports 310 can be movable in unison to reposition display device as desired by a user.

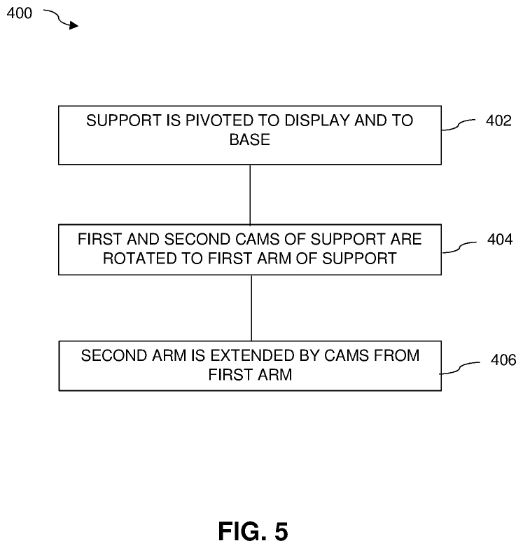

FIG. 5 is a flow chart of an example method 400 of repositioning a support coupled to a display device in accordance with aspects of the present disclosure. At 402, support is pivoted to display and to base. At 404, first and second cams of support are rotated to first arm of support. At 406, second arm is extended by cams from first arm.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

1. A support for a display device, comprising:
a first arm having a first end, an opposing second end, and a body extending between the first end and the second end, the body having a length and a width, the first end pivotably coupled to a display device, the second end pivotably coupled to a base;
a first cam and a second cam coupled to the first arm; and
a second arm extending along the body of the first arm, the second arm having a proximal end and a distal end, the proximal end of the second arm movably coupled to the first arm at the first cam, and the distal end of the second arm movably coupled to the first arm at the second cam, the second arm extending within the width and the length of the first arm in a retracted state, and the second arm extending outside of the width and within the length of the first arm in an extended state.

2. The support of claim 1, wherein the second arm having a length less than the first arm.

3. The support of claim 1, wherein the first arm includes a recessed area to accommodate the second arm.

4. The support of claim 1, wherein the first and second cams each include a stop portion to limit movement of the second arm.

5. The support of claim 1, wherein the display device is rotatable about a first axis defined at the first end coupling and movable along an arc having an arc length from the base.

6. The support of claim 5, wherein the arc length is limited by the first and second cams.

7. The support of claim 1, wherein the first arm is formed as a first U-shaped channel including a first open side and the second arm is a second U-shaped channel including a second open side, wherein the second arm is extendable outside first open side of the first arm.

8. A stand for a display device comprising:
a base;
a support extending between the base and the display device, the support to provide adjustable movement to the display device from the base, the support including:
a first arm having a first end and a second end, the first end pivotably coupled to the base and the second end pivotably coupled to the display device,
a second arm extending between the first end and the second end of the first arm, and
a first cam and a second cam movably coupled between the first arm and the second arm, the second arm movable to the first arm at the first cam and the second cam,
wherein the first and second cams are movable in response to pivotal movement of the first arm.

9. The stand of claim 8, wherein the support includes a cavity to house cables extending from the display device.

10. The stand of claim 8, wherein the first arm and the second arm are channels and the second arm is disposable within the first arm.

11. The stand of claim 8, wherein second arm is extendable within a width and a length of the first arm.

12. The stand of claim 8, wherein the support includes a pair of supports, each of the pair of supports extending between the display device and the base.

13. A display system, comprising:
a display device;
a base coupled to the display device;
a support extending between the display device and the base, the support comprising:
a first arm having a first end, an opposing second end, and a body extending between the first end and the second end, the body having a length and a width, the first end pivotably coupled to the display device, the second end pivotably coupled to the base;
a first cam and a second cam coupled to the first arm; and
a second arm extending along the body of the first arm, the second arm having a proximal end and a distal end, the proximal end of the second arm movably coupled to the first arm at the first cam and the distal end of the second arm movably coupled to the first arm at the second cam,
wherein the display device is movable between a first position and a second position, in the first position the second arm extends within a width and the length of the first arm, and in the second position the second arm extends outside of the width and within the length of the first arm, and
wherein the display device is rotatable about a first axis defined at the first end coupling and movable along an arc having an arc length from the base.

14. The display system of claim 13, wherein in the first arm has an first open side extending along a longitudinal axis of the support and the second arm has an second open side extending along a first closed side of the first arm opposite the first open side.

15. The display system of claim 14, wherein the second arm includes a second closed side opposite the second open side and second opposing legs extending from the second closed side to the second open side, wherein the second closed side and opposing legs arm are selectively extendable within the first arm.
